(19) United States
(12) Patent Application Publication
(10) Pub. No.: US 2024/0240322 A1
(43) Pub. Date: Jul. 18, 2024

(54) PROCESS CHAMBER HAVING SHUTTER COVER FOR SUBSTRATE UNIFORMITY AND PREVENTION OF UNINTENDED DEPOSITION

(71) Applicant: Applied Materials, Inc., Santa Clara, CA (US)

(72) Inventors: Abhishek CHOWDHURY, Bangalore (IN); Edwin C. SUAREZ, Pleasanton, CA (US); Xiaozhou CHE, Santa Clara, CA (US); Arun Chakravarthy CHAKRAVARTHY, Tamil Nadu (IN); Harisha SATHYANARAYANA, Bangalore (IN); Nataraj BHASKAR RAO, Bangalore (IN)

(21) Appl. No.: 18/096,533

(22) Filed: Jan. 12, 2023

(51) Int. Cl. C23C 16/52; C23C 16/455; C23C 16/458

(52) U.S. Cl. CPC C23C 16/52; C23C 16/45565; C23C 16/4585

(57) ABSTRACT

Embodiments of process chambers are provided herein. In some embodiments, a process chamber includes: a chamber body having a bottom plate, a lid, and sidewalls extending from the bottom plate to the lid, wherein one of the sidewalls includes a shutter recess, wherein the chamber body and the shutter recess define an interior volume of the process chamber; a substrate support for supporting a substrate disposed in the interior volume; a showerhead disposed in the interior volume opposite the substrate support; and a shutter cover having a shutter disk coupled to a shutter arm, wherein the shutter cover is disposed in the interior volume and rotatably coupled to the chamber body between a home position and a cover position, wherein in the home position, the shutter cover is at least partially disposed in the shutter recess, and wherein in the cover position, the shutter cover extends over the substrate support.

### FIELD

Embodiments of the present disclosure generally relate to substrate processing equipment and methods of processing a substrate.

### BACKGROUND

In semiconductor wafer processing, process chambers, such as chemical vapor deposition (CVD) chambers, are used to form layers of materials within integrated circuits. The deposition chamber may include a showerhead for dispersing process fluids into the deposition chamber. Typically, after completion of a deposition process in the process chamber, a substrate, or wafer, being processed is removed from the process chamber. However, unintended additional deposition may continue on the substrate after completion of the deposition process and prior to removal. For example, due to issues like condensation of process fluids upstream of the showerhead, some unintended deposition occurs even after the process/flow of process fluids is stopped. Also, residual material in the source delivery system line may cause extra deposition on the substrate

Accordingly, the inventors have provided herein embodiments of improved process chambers having a shutter cover for improving wafer nonuniformity and prevention of unintended additional deposition.

### SUMMARY

Embodiments of process chambers are provided herein. In some embodiments, a process chamber includes: a chamber body having a bottom plate, a lid, and sidewalls extending from the bottom plate to the lid, wherein one of the sidewalls includes a shutter recess, wherein the chamber body and the shutter recess define an interior volume of the process chamber; a substrate support for supporting a substrate disposed in the interior volume; a showerhead disposed in the interior volume opposite the substrate support; and a shutter cover having a shutter disk coupled to a shutter arm, wherein the shutter cover is disposed in the interior volume and rotatably coupled to the chamber body between a home position and a cover position, wherein in the home position, the shutter cover is at least partially disposed in the shutter recess and exposes the substrate support to the showerhead, and wherein in the cover position, the shutter cover extends over the substrate support.

In some embodiments, a deposition chamber includes: a chamber body having a bottom plate, a lid, and sidewalls extending from the bottom plate to the lid; a shutter recess extending from one of the sidewalls of the chamber body, wherein the chamber body and the shutter recess define an interior volume of the deposition chamber; a substrate support for supporting a substrate disposed in the interior volume; a showerhead disposed in the interior volume opposite the substrate support; and a shutter cover that is one-piece and comprising a shutter disk and a shutter arm extending from the shutter disk, wherein the shutter cover is disposed in the interior volume and rotatably coupled to the chamber body via a support shaft coupled to the bottom plate.

In some embodiments, a method of processing a substrate includes: performing a deposition process on a substrate in a process chamber; rotating a shutter cover disposed in an interior volume of the process chamber from a home position, where the shutter cover is at least partially disposed in a shutter recess such that a substrate support in the process chamber is exposed to a showerhead disposed in the process chamber, to a cover position, where the shutter cover is disposed out of the shutter recess and covers the substrate support and the substrate disposed thereon; with the shutter cover disposed over the substrate support, transferring the substrate out of the process chamber; with the shutter cover disposed over the substrate support, transferring a new substrate into the process chamber; and after the new substrate is disposed atop the substrate support, rotating the shutter cover from the cover position to the home position.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic cross-sectional side view of a process chamber in accordance with at least some embodiments of the present disclosure.

FIG. 2A depicts a cross-sectional top view of a process chamber with a shutter cover in a home position in accordance with at least some embodiments of the present disclosure.

FIG. 2B depicts a cross-sectional top view of a process chamber with a shutter cover in a cover position in accordance with at least some embodiments of the present disclosure.

FIG. 3 depicts a flow chart of a method of processing a substrate in accordance with at least some embodiments of the present disclosure.

FIG. 4A depicts a schematic side sectional view of a process chamber in a process position in accordance with at least some embodiments of the present disclosure.

FIG. 4B depicts a schematic side sectional view of a process chamber with the shutter cover in a cover position in accordance with at least some embodiments of the present disclosure.

FIG. 4C depicts a schematic side sectional view of a process chamber with a substrate in a raised position supported by lift pins in accordance with at least some embodiments of the present disclosure.

FIG. 4D depicts a schematic side sectional view of a process chamber with a substrate supported on a transfer blade for removal in accordance with at least some embodiments of the present disclosure.

FIG. 4E depicts a schematic side sectional view of a process chamber with no substrate in the process chamber and a shutter cover in a cover position in accordance with at least some embodiments of the present disclosure.

FIG. 4F depicts a schematic side sectional view of a process chamber with a shutter cover in a cover position and a new substrate supported by lift pins in accordance with at least some embodiments of the present disclosure.

FIG. 5A depicts a schematic side sectional view of a process chamber configured for a cleaning process in accordance with at least some embodiments of the present disclosure.

FIG. 5B depicts a schematic side sectional view of a process chamber configured for a seasoning process in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of process chambers having a shutter cover are provided herein. The shutter cover is disposed in the process chamber and is rotatable between a cover position, where the shutter cover is disposed between a substrate support and a showerhead, and a home position, where the shutter cover exposes the substrate support to the showerhead. Unintended deposition on a substrate or substrate support may occur after gas shut off during substrate processing due to condensation of process gases, or precursor, in the showerhead or gas supply lines. The shutter cover advantageously may cover the substrate when the substrate is not being processed to prevent unwanted deposition on the substrate. The shutter cover advantageously also may cover the substrate support when a substrate is not disposed thereon to prevent unwanted deposition on the substrate support, for example, during substrate transfer. Substrate non-uniformity advantageously may be reduced as the unintended additional deposition on the substrate is eliminated.

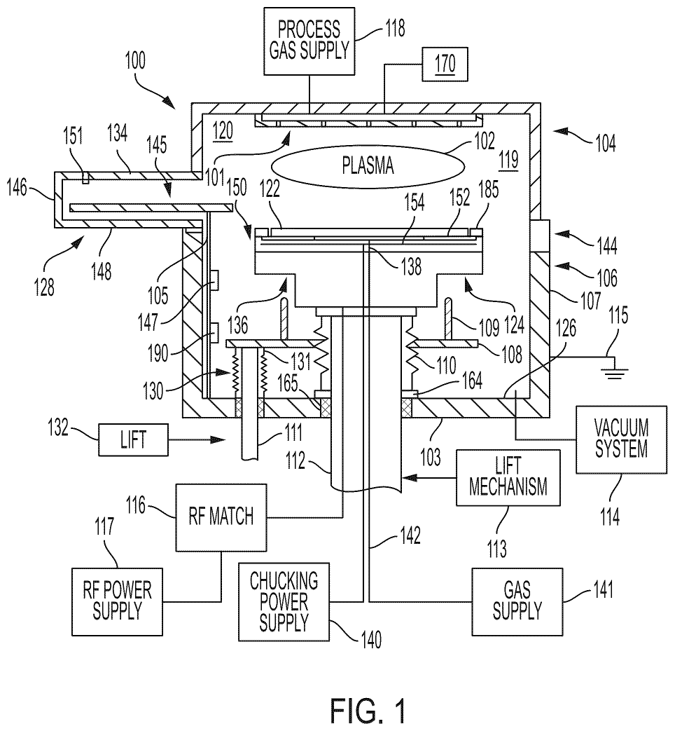

FIG. 1 depicts a schematic side view of a process chamber in accordance with at least some embodiments of the present disclosure. In some embodiments, the process chamber 100 is a deposition processing chamber. The process chamber 100 is generally a vacuum chamber that is suitably adapted to maintain sub-atmospheric pressures within an interior volume 120 during substrate processing. The process chamber 100 includes a chamber body 106 having a bottom plate 103, a lid 104, and sidewalls 107 extending from the bottom plate 103 to the lid 104. One or more of the sidewalls 107 include a shutter recess 128 having a suitable shape extending from the sidewall 107 to accommodate a shutter cover 145. The chamber body 106 and the shutter recess 128 define the interior volume 120 of the process chamber 100. In some embodiments, the shutter recess 128 is defined by a shutter top plate 134, a shutter bottom plate 148, and sidewalls 146 extending from the shutter bottom plate 148 to the shutter top plate 134. In some embodiments, the sidewalls 146 comprise a plurality of flat sidewalls that are angled with respect to each other. In some embodiments, the sidewalls 146 may be one or more curved walls.

A substrate support 124 is disposed within the interior volume 120 to support and retain a substrate 122, such as a semiconductor wafer, for example, or other such substrate as may be retained. The substrate support 124 may generally comprise a pedestal 150 coupled to a hollow shaft 112. The pedestal 150 comprises a dielectric plate 152 disposed on a base assembly 136. The substrate support 124 may include an edge ring 185 disposed on the dielectric plate 152. The dielectric plate 152 may include one or more chucking electrodes 154 configured to electrostatically chuck the substrate 122 to the dielectric plate 152. The one or more chucking electrodes 154 may also electrostatically chuck the edge ring 185 to the dielectric plate 152.

The hollow shaft 112 provides a conduit to provide, for example, backside gases, process gases, fluids, coolants, power, or the like, to the pedestal 150. In some embodiments, the hollow shaft 112 is coupled to a lift mechanism 113, such as an actuator or motor, which provides vertical movement of the pedestal 150 between an upper, processing position and a lower, transfer position. A bellows assembly 110 is disposed about the hollow shaft 112 and is coupled between the pedestal 150 and a bottom surface 126 of the process chamber 100 to provide a flexible seal that allows vertical motion of the pedestal 150 while preventing loss of vacuum from within the process chamber 100. The bellows assembly 110 also includes a lower bellows flange 164 in contact with an o-ring 165 or other suitable sealing element which contacts the bottom surface 126 to help prevent loss of chamber vacuum.

A showerhead 101 is disposed in the interior volume 120 proximate the lid 104 and opposite the substrate support 124 for delivering process gases into the interior volume 120. The process chamber 100 is coupled to and in fluid communication with a process gas supply 118 which may supply one or more process gases to the process chamber 100 for processing the substrate 122. The interior volume 120 may include a processing volume 119 located in the upper half of the interior volume 120 and generally between the substrate support 124 and the showerhead 101. The process chamber 100 may also include one or more shields (not shown) circumscribing various chamber components to prevent unwanted reaction between such components and ionized process material. The chamber body 106 may be made of metal, such as aluminum. The chamber body 106 may be grounded via a coupling to ground 115.

In some embodiments, the hollow shaft 112 facilitates coupling a backside gas supply 141, a chucking power supply 140, and RF sources (e.g., RF plasma power supply 170 and a bias power supply 117) to the pedestal 150. In some embodiments, the bias power supply 117 includes one or more RF bias power sources. In some embodiments, RF energy supplied by the RF plasma power supply 170 may have a frequency of about 400 kHz to over 40 MHz. The backside gas supply 141 is disposed outside of the chamber body 106 and supplies heat transfer gas to the pedestal 150. In some embodiments, a RF plasma power supply 170 and a bias power supply 117 are coupled to the pedestal 150 via respective RF match networks (only RF match network 116 shown). In some embodiments, the substrate support 124 may alternatively include AC, DC, or RF bias power. In some embodiments, the AC, DC, or RF bias power may be pulsed.

The process chamber 100 may include a second lift 130. The second lift 130 can include lift pins 109 mounted on a platform 108 connected to a shaft 111 which is coupled to a second lift mechanism 132 for raising and lowering the second lift 130 so that the substrate 122 may be placed on or removed from the pedestal 150. In some embodiments, each of the lift pins 109 are not mounted to a common platform and are independently controllable. The pedestal 150 may include through holes to receive one or more of the lift pins 109. A bellows assembly 131 is coupled between the second lift 130 and bottom surface 126 to provide a flexible seal which maintains the chamber vacuum during vertical motion of the second lift 130. In some embodiments, as shown in FIG. 1, the second lift 130 is disposed outside of the hollow shaft 112.

In some embodiments, the pedestal 150 includes gas distribution channels 138 extending from a lower surface of the pedestal 150 (e.g., bottom surface of the base assembly 136) to various openings in an upper surface of the pedestal 150. The gas distribution channels 138 are configured to provide backside gas, such as nitrogen (N) or helium (He), to the top surface of the pedestal 150 to act as a heat transfer medium. The gas distribution channels 138 are in fluid communication with the backside gas supply 141 via gas conduit 142 to control the temperature and/or temperature profile of the pedestal 150 during use. In some embodiments, the gas distribution channels 138 are configured to provide gas pressure for heat transfer and temperature control of the edge ring 185 independently from a temperature of the dielectric plate 152.

The process chamber 100 is coupled to and in fluid communication with a vacuum system 114 which includes a throttle valve (not shown) and vacuum pump (not shown) which are used to exhaust the process chamber 100. The pressure inside the process chamber 100 may be regulated by adjusting the throttle valve and/or vacuum pump.

The process chamber 100 includes a slit valve 144 having a substrate transfer opening that is selectively opened or closed to facilitate transferring the substrate 122 into and out of the interior volume 120. In some embodiments, a transfer robot (not shown) having one or more transfer blade (see transfer blade 410) is configured to transfer the substrate 122. In some embodiments, the shutter recess 128 is disposed vertically above the substrate transfer opening of the slit valve 144.

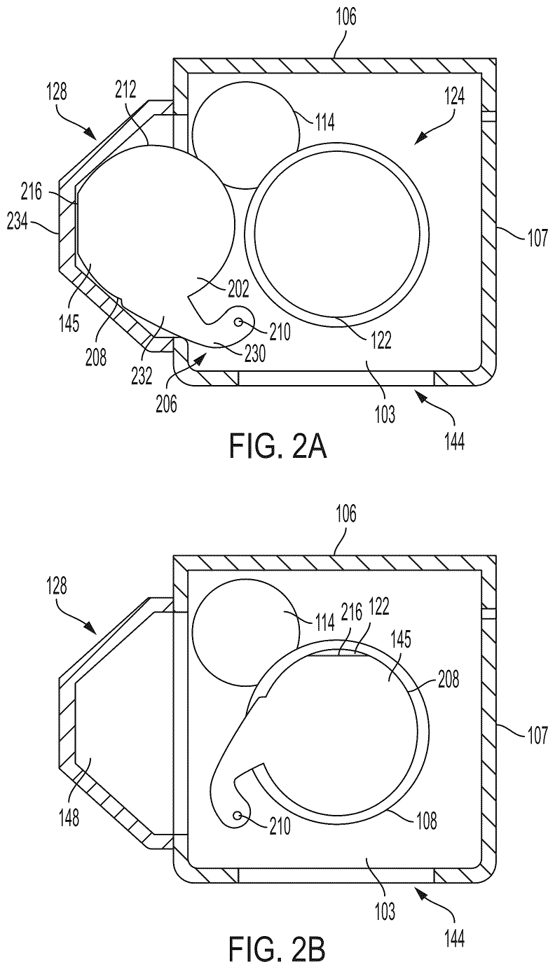

A shutter cover 145 is disposed in the interior volume 120 and rotatably coupled in the chamber body 106 between a home position (as shown in FIG. 1 and FIG. 2A) and a cover position (as shown in FIG. 2B). In the home position, the shutter cover 145 is at least partially disposed in the shutter recess 128 and exposes the substrate support 124 to the showerhead 101. In the cover position, the shutter cover 145 extends over the substrate support 124. In some embodiments, a position sensor 151 is disposed in the shutter recess 128 and configured to indicate a position of the shutter cover 145. For example, the position sensor 151 may indicate when the shutter cover 145 is in the home position and when the shutter cover 145 is not in the home position.

In some embodiments, the shutter cover 145 is rotatably coupled to the bottom plate 103 of the chamber body 106 via a support shaft 105. In some embodiments, the support shaft 105 is configured for rotational and vertical movement such that the shutter cover 145 is configured for rotational and vertical movement. In some embodiments, the support shaft 105 includes a shutter lift 147 to facilitate vertical movement of the shutter cover 145. In some embodiments, the support shaft 105 includes a motor 190 to facilitate rotational movement of the shutter cover 145. In some embodiments, when the substrate support 124 is in a transfer position (as shown in FIG. 1), the shutter recess 128 extends vertically between the substrate support 124 and the showerhead 101.

In operation, for example, a plasma 102 may be created in the interior volume 120 to perform one or more processes. The plasma 102 may be created by coupling power from a plasma power source (e.g., RF plasma power supply 170) to a process gas via one or more electrodes near or within the interior volume 120 to ignite the process gas and creating the plasma 102. A bias power may be provided from a bias power supply (e.g., bias power supply 117) to the pedestal 150 to attract ions from the plasma 102 towards the substrate 122. The bias power supply 117 may supply bias power to the edge ring 185 and the dielectric plate 152. For example, the bias power supply 117 may comprise a single power supply that is shared by both the edge ring 185 and the dielectric plate 152. The shutter cover 145 may be rotated to cover the substrate support 124 when processing is complete to avoid unwanted deposition on the substrate 122 or substrate support 124.

FIG. 2A depicts a cross-sectional top view of a process chamber with a shutter cover in a home position in accordance with at least some embodiments of the present disclosure. In the home position, the shutter cover 145 is at least partially disposed in the shutter recess 128. In some embodiments, in the home position, more than half of the shutter cover 145 is disposed in the shutter recess 128. FIG. 2B depicts a cross-sectional top view of a process chamber with a shutter cover in a cover position in accordance with at least some embodiments of the present disclosure. In some embodiments, in the cover position, the shutter cover 145 is entirely disposed outside of the shutter recess 128. The shutter cover 145 is configured to rotate about an axis of rotation 210. In some embodiments, the axis of rotation 210 is disposed outside of the shutter recess 128.

The shutter cover 145 generally includes a shutter disk 202 coupled to a shutter arm 206. The shutter disk 202 may generally be a circular disk. In some embodiments, an upper edge 208 of the shutter disk 202 includes a curved portion 212 and a linear portion 216. When in the home position, the linear portion 216 may face an outermost sidewall 234 of the shutter recess 128 and advantageously require a smaller sized shutter recess 128 as compared to the shutter disk 202 having the curved portion 212 extending along an entire length of the upper edge 208. In some embodiments, the shutter arm 206 includes a first portion 230 and a second portion 232, where the second portion 232 is disposed between the first portion 230 and the shutter disk 202. The shutter arm 206 may be designed to reduce the shutter cover 145 footprint. For example, in some embodiments, the first portion 230 extends from the axis of rotation 210 in a first direction and the second portion 232 extends from the first portion to the shutter disk 202 in a second direction different than the first direction.

In some embodiments, the shutter cover 145 is a unibody, or one-piece, component. In some embodiments, the shutter cover 145 is made of a metal or ceramic material. A thickness of the shutter disk 202 may be thick enough to prevent bending while thin enough to minimize weight. For example, in some embodiments, the shutter disk 202 may be about 0.2 inches thick or less. In some embodiments, the shutter cover is configured to rotate about 75 to about 105 degrees about an axis of rotation 210 to move from the home position to the cover position. In some embodiments, the shutter cover is configured to rotate about 85 to about 95 degrees about the axis of rotation 210 to move from the home position to the cover position.

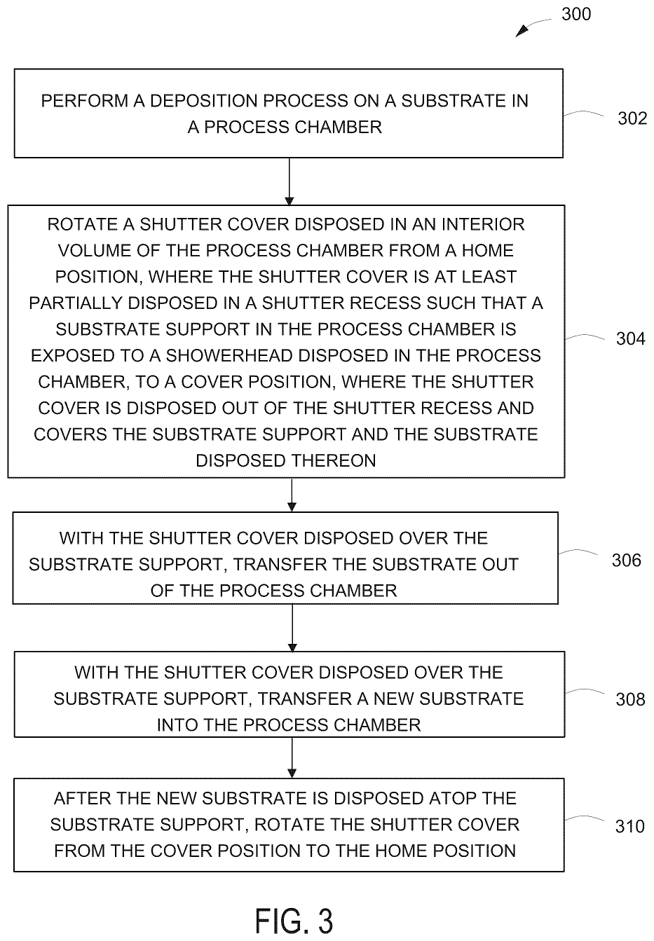

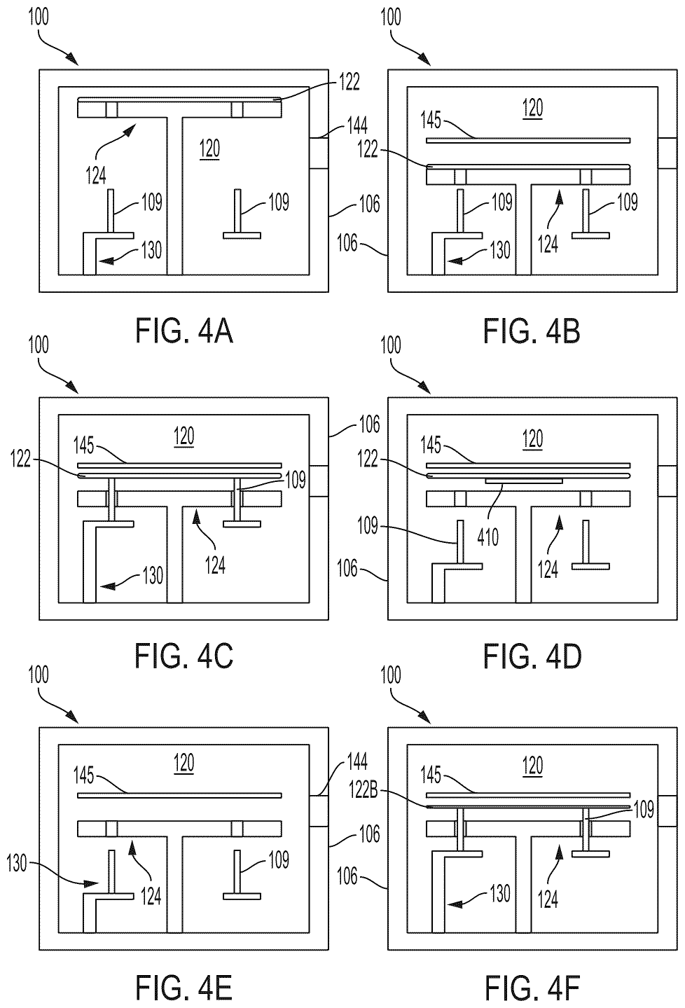

FIG. 3 depicts a flow chart of a method 300 of processing a substrate (e.g., substrate 122) in accordance with at least some embodiments of the present disclosure. At 302, the method 300 includes performing a deposition process on a substrate in a process chamber (e.g., process chamber 100). In some embodiments, the deposition process is a CVD deposition process or a plasma enhanced CVD process. FIG. 4A depicts a schematic side view of a process chamber in a deposition process position in accordance with at least some embodiments of the present disclosure.

After processing is complete, the substrate support may be lowered to a transfer position as depicted in FIG. 4B. At 304, the method 300 includes rotating a shutter cover (e.g., shutter cover 145) disposed in an interior volume (e.g., interior volume 120) of the process chamber from a home position, where the shutter cover is at least partially disposed in a shutter recess (e.g., shutter recess 128) such that a substrate support (e.g., substrate support 124) in the process chamber is exposed to a showerhead (e.g., showerhead 101) disposed in the process chamber, to a cover position as depicted in FIG. 4B, where the shutter cover is disposed out of the shutter recess and covers the substrate support and the substrate disposed thereon. In some embodiments, rotating the shutter cover between the home position and the cover position comprises rotating the shutter cover by about 75 to about 105 degrees. In some embodiments, the rotation is in a clockwise direction. In some embodiments, the chamber body 106 prevents the shutter cover from rotating more than 180 degrees from the home position. In some embodiments, the axis of rotation of the shutter cover is disposed outside of the shutter recess, for example within a chamber body (e.g., chamber body 106) of the process chamber. FIG. 4B depicts a schematic side view of a process chamber with the shutter cover in the cover position in accordance with at least some embodiments of the present disclosure.

In some embodiments, as depicted in FIG. 4C, the method 300 further comprises lifting the substrate off of the substrate support via lift pins (e.g., lift pins 109) after rotating the shutter cover to the cover position. In some embodiments, as depicted in FIG. 4D, a transfer blade (e.g., transfer blade 410) is moved into the process chamber between the substrate and the substrate support after lifting the substrate off of the substrate support. In some embodiments, the method 300 includes lowering the lift pins so that the substrate rests on the transfer blade prior to transferring the substrate out of the process chamber. The lift pins may be lowered below an upper surface of the substrate support as depicted in FIG. 4D.

At 306, the method 300 includes transferring the substrate out of the process chamber with the shutter cover disposed over the substrate support. The substrate may be transferred via the transfer blade or any other suitable method. In some embodiments, the method 300 comprises raising the shutter cover, via for example a shutter lift (e.g., shutter lift 147) prior to transferring the substrate out of the process chamber. The shutter cover may be raised to provide adequate clearance for a transfer blade to move below the substrate. FIG. 4E depicts a process chamber after the processed substrate is removed from the interior volume 120.

At 308, the method 300 includes transferring a new substrate (e.g., new substrate 122B) into the process chamber with the shutter cover disposed over the substrate support. In some embodiments, the method 300 includes using a transfer blade to transfer the new substrate into the process chamber. The transfer blade for transferring the new substrate into the process chamber may be the same transfer blade used to remove the processed substrate (i.e., first transfer blade) or can be a different transfer blade, for example, a second transfer blade. The second transfer blade may be disposed at a different height than the first transfer blade and the shutter lift may be used to adjust the height of the shutter cover as needed. In some embodiments, a plurality of lift pins are raised to lift up the new substrate off of the transfer blade. The transfer blade can then be removed from the interior volume so the new substrate rests on the plurality of lift pins as depicted in FIG. 4F. The plurality of lift pins may then be lowered to lower the new substrate onto the substrate support.

In some embodiments, the method 300 further comprises performing a seasoning process in the process chamber after transferring the substrate out of the process chamber and before transferring a new substrate into the process chamber. Seasoning generally refers to a process of depositing a material on interior surfaces of the process chamber similar to or the same as the material to be deposited on substrates being processed therein for the purpose of preventing impurities into the film deposited and improving uniformity of the film thickness.

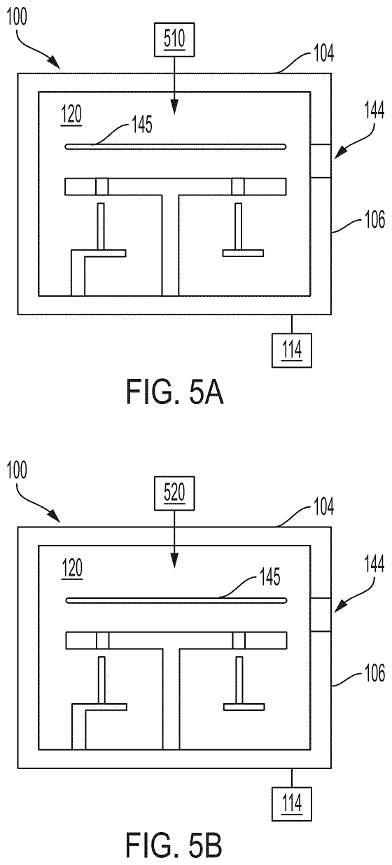

In some embodiments, a cleaning process may be performed prior to the seasoning process to remove residues and impurities deposited onto chamber walls or other chamber components. For example, FIG. 5A depicts a schematic side view of a process chamber configured for a cleaning process. In some embodiments, the shutter cover remains in the cover position during the cleaning process. The cleaning process may be any suitable wet or dry cleaning process. For example, in some embodiments, a cleaning gas source 510 is coupled to the process chamber 100 for delivering a cleaning gas, such as an etchant gas into the interior volume 120.

FIG. 5B depicts a schematic side view of a process chamber configured for a seasoning process in accordance with at least some embodiments of the present disclosure. In some embodiments, the shutter cover remains in the cover position during the seasoning process. Seasoning precursor gas is introduced into the interior volume 120 from a seasoning precursor gas source 520 to form a seasoning film on the interior surfaces of the process chamber to prevent the excessive accumulation of particles in the process chamber. In some embodiments, a purge process is performed (e.g., via vacuum system 114) after the cleaning process, after the seasoning process, or both cleaning and seasoning processes to remove residual process gases from the interior volume 120 prior to transferring a new substrate into the process chamber. At 310, the method 300 includes rotating the shutter cover from the cover position to the home position after the new substrate is disposed atop the substrate support. The new substrate may then undergo processing.

While the foregoing is directed to embodiments of the present disclosure, other and further embodiments of the disclosure may be devised without departing from the basic scope thereof.

1. A process chamber, comprising:
a chamber body having a bottom plate, a lid, and sidewalls extending from the bottom plate to the lid, wherein one of the sidewalls includes a shutter recess, wherein the chamber body and the shutter recess define an interior volume of the process chamber;
a substrate support for supporting a substrate disposed in the interior volume;
a showerhead disposed in the interior volume opposite the substrate support; and
a shutter cover having a shutter disk coupled to a shutter arm, wherein the shutter cover is disposed in the interior volume and rotatably coupled to the chamber body between a home position and a cover position, wherein in the home position, the shutter cover is at least partially disposed in the shutter recess and exposes the substrate support to the showerhead, and wherein in the cover position, the shutter cover extends over the substrate support.

2. The process chamber of claim 1, wherein the shutter cover is rotatably coupled to the bottom plate of the chamber body via a support shaft.

3. The process chamber of claim 2, wherein the support shaft is configured for vertical movement.

4. The process chamber of claim 1, wherein the shutter cover is configured to rotate about 75 to about 105 degrees about an axis of rotational to move from the home position to the cover position.

5. The process chamber of claim 4, wherein an upper edge of the shutter disk includes a curved portion and a linear portion.

6. The process chamber of claim 1, wherein the shutter recess is defined by a shutter top plate, a shutter bottom plate, and sidewalls extending from the shutter bottom plate to the shutter top plate.

7. The process chamber of claim 1, wherein the shutter cover is a unibody component.

8. The process chamber of claim 1, further comprising a position sensor disposed in the shutter recess configured to indicate a position of the shutter cover.

9. The process chamber of claim 1, wherein the shutter cover is made of a metal or ceramic material.

10. A deposition chamber, comprising:
a chamber body having a bottom plate, a lid, and sidewalls extending from the bottom plate to the lid;
a shutter recess extending from one of the sidewalls of the chamber body, wherein the chamber body and the shutter recess define an interior volume of the deposition chamber;
a substrate support for supporting a substrate disposed in the interior volume;
a showerhead disposed in the interior volume opposite the substrate support; and
a shutter cover that is one-piece and comprising a shutter disk and a shutter arm extending from the shutter disk, wherein the shutter cover is disposed in the interior volume and rotatably coupled to the chamber body via a support shaft coupled to the bottom plate.

11. The deposition chamber of claim 10, further comprising a plurality of lift pins disposed in the interior volume and configured to raise or lower the substrate with respect to the substrate support.

12. The deposition chamber of claim 10, wherein the chamber body includes a substrate transfer opening, and wherein the shutter recess is disposed vertically above the substrate transfer opening.

13. The deposition chamber of claim 10, wherein the support shaft is configured for rotational and vertical movement.

14. The deposition chamber of claim 10, wherein, when the substrate support is in a transfer position, the shutter recess extends vertically between the substrate support and the showerhead.

15. A method of processing a substrate, comprising:
performing a deposition process on the substrate in a process chamber;
rotating a shutter cover disposed in an interior volume of the process chamber from a home position, where the shutter cover is at least partially disposed in a shutter recess such that a substrate support in the process chamber is exposed to a showerhead disposed in the process chamber, to a cover position, where the shutter cover is disposed out of the shutter recess and covers the substrate support and the substrate disposed thereon;
with the shutter cover disposed over the substrate support, transferring the substrate out of the process chamber;
with the shutter cover disposed over the substrate support, transferring a new substrate into the process chamber; and
after the new substrate is disposed atop the substrate support, rotating the shutter cover from the cover position to the home position.

16. The method of claim 15, further comprising lifting the substrate off of the substrate support via lift pins after rotating the shutter cover to the cover position; and
moving a transfer blade into the process chamber between the substrate and the substrate support; and
and lowering the lift pins so that the substrate rests on the transfer blade prior to transferring the substrate out of the process chamber.

17. The method of claim 15, further comprising:
using a transfer blade to transfer the new substrate into the process chamber; and
using a plurality of lift pins to lower the new substrate from the transfer blade to the substrate support.

18. The method of claim 15, further comprising:
raising the shutter cover prior to transferring the substrate out of the process chamber.

19. The method of claim 15, further comprising performing a seasoning process in the process chamber after transferring the substrate out of the process chamber and before transferring the new substrate into the process chamber.

20. The method of claim 15, wherein rotating the shutter cover between the home position and the cover position comprises rotating the shutter cover by about 75 to about 105 degrees.
